(19) United States
(12) Patent Application Publication
(10) Pub. No.: US 2007/0008999 A1
(43) Pub. Date: Jan. 11, 2007

(54) Broadened waveguide for interband cascade lasers

(75) Inventors: Nicholas P. Breznay, Laurel, MD (US); John D. Bruno, Bowie, MD (US)

Correspondence Address: Alan G. Towner;Pietragallo, Bosick & Gordon, One Oxford Centre, 38th Floor, 301 Grant Street, Pittsburgh, PA, 15219, US

(73) Assignee: Maxion Technologies, Inc.

(21) Appl. No.: 11/146,754

(22) Filed: Jun. 7, 2005

Related U.S. Application Data
(60) Provisional application No. 60/577,563, filed on Jun. 7, 2004.

(51) Int. Cl. H01S 5/00; H01S 3/04

(52) U.S. Cl. 372/45.01; 372/43.01

(57) ABSTRACT

Interband cascade lasers having high-refractive index semiconductor spacer layers within the active regions are disclosed. Together with spacer layers which may be provided outside the active regions, broadened waveguides are formed which increase brightness and decrease divergence of the lasers. In one embodiment, current may be supplied laterally through the high-refractive index spacer layers. Carriers may be injected vertically through the active region from these contact layers, allowing selective functionality of some or all of the active region cascaded stages.

### CROSS-REFERENCE TO RELATED APPLICATION

This application claims the benefit of U.S. Provisional Patent Application Ser. No. 60/577,563 filed Jun. 7, 2004, which is incorporated herein by reference.

### GOVERNMENT CONTRACT

The United States Government has certain rights to this invention pursuant to Contract No. W15P7T-04-C-K404 awarded by the U.S. Army Communications-Electronics Command.

### FIELD OF THE INVENTION

The present invention relates to interband cascade lasers, and more particularly relates to the use of spacer layers within the active regions of such lasers to increase the thickness of the waveguides of such lasers.

### BACKGROUND INFORMATION

Interband cascade lasers have active light-emitting regions sandwiched between cladding layers. Examples of interband cascade lasers are disclosed in U.S. Pat. Nos. 5,588,015 and 6,404,791, and published U.S. patent application Ser. Nos. 2004/0223528 and 2004/0223529, which are incorporated herein by reference.

Although conventional interband cascade lasers have many beneficial characteristics, it would be desirable to increase the brightness and decrease the laser beam divergence of such lasers.

### SUMMARY OF THE INVENTION

The present invention provides interband cascade lasers including high-refractive index spacer layers within the active region of the laser structure. The spacer layers within the active region may be located between the cascaded stages. Spacer layers may also be provided outside the active region. A broadened waveguide is formed which increases brightness and decreases divergence of the lasers. In one embodiment, current may be supplied laterally through the high-refractive index spacer layers, if they are doped appropriately. Carriers may be injected vertically through the active region from these contact layers, allowing selective functionality of some or all of the active region cascaded stages. This allows for precise control of the mode profile and optical confinement in the active region, a reduction in the linewidth enhancement factor, and improved tunability if ohmic contact is made to one or more of the layers sandwiched within the active region. If desired, unused active regions can be selectively biased to reduce or eliminate absorption at the lasing wavelength of the used sections.

An aspect of the present invention is to provide an interband cascade laser structure comprising a first pair of active and injection layers, a second pair of active and injection layers, and a spacer layer between the first and second pairs of active and injection layers.

Another aspect of the present invention is to provide an interband cascade laser structure comprising multiple repeating unit layers. Each unit layer comprises an active layer, a spacer layer on the active layer, and an injection layer on the spacer layer.

A further aspect of the present invention is to provide an interband cascade laser structure comprising a bottom cladding layer, a bottom spacer layer over the bottom cladding layer, a transition layer over the bottom spacer layer, a first active layer over the bottom spacer layer, a second spacer layer over the first active layer, a first injection layer over the second spacer layer, a second active layer over the first injection layer, a top spacer layer over the second active layer, and a top cladding layer over the top spacer layer.

These and other aspects of the present invention will be more apparent from the following description.

### BRIEF DESCRIPTION OF THE DRAWINGS

FIG. 1 is a partially schematic side view of an interband cascade laser including spacer layers within and surrounding the active region of the laser in accordance with an embodiment of the present invention.

FIG. 2 is a partially schematic side view of an interband cascade laser including two cascaded stages and high-retractive index spacer layers which also serve as current injection layers in accordance with an embodiment of the present invention.

FIGS. 3a-3c are partially schematic side views of the multiple-stage interband cascade laser of FIG. 2, illustrating three different modes of operation. In FIG. 3a, only the upper cascaded stage is activated. In FIG. 3b, only the lower cascaded stage is activated. In FIG. 3c, both the upper and lower cascaded stages are activated.

FIG. 4 is a graph of active-injection core optical confinement versus GaSb spacer layer thickness, illustrating that optical confinement is optimized with a spacer layer having a thickness of about 0.2 micrometers.

FIG. 5 is a graph of mode intensity versus epilayer position for an interband cascade laser structure having a single intermediate spacer layer within the active region of the laser.

FIG. 6 is a graph of mode intensity versus epilayer position for an interband cascade laser structure having two intermediate spacer layers within the active region of the laser.

FIG. 7 is a graph of mode intensity versus position, illustrating a calculated optical mode profile for an interband cascade laser structure having spacer layers in accordance with an embodiment of the present invention.

### DETAILED DESCRIPTION

In accordance with the present invention, spacer layers are placed within, and may also be placed adjacent to, an active region in an interband cascade semiconductor laser structure. In one embodiment, electrically conductive doped spacer layers are sandwiched between cascaded stages of the laser active region, and either doped or undoped spacer layers are placed at either end of the entire core active region structure. The thickness and number of the high refractive index spacer layers within and surrounding the active region may be selected to increase the optical confinement of the laser mode within the active region. The waveguide core thickness is widened by the spacer layers to increase the width of the optical mode, which increases the brightness of the laser. Also, the linewidth enhancement factor is reduced. The doping levels of the spacer layers may be controlled in order to minimize free carrier losses, while maintaining a low electrical resistance to facilitate carrier transport through the material. The doped spacer layers may be used for selective current injection into particular active-injection stages in a cascade laser geometry.

As used herein, the term “active layer” means the region of a laser structure in which light is generated for radiation from the structure. The term “injection layer” means a layer of material or materials which conduct electrical current to or from the active layers of the structure. At least a portion of the injection layer may be oriented in a plane substantially parallel with the plane of the active layer. The injection layers may be partially or entirely coextensive with the adjacent active layers. As used herein, the term “cladding layer” means any type of cladding, reflector or mirror layer located outside of the active region of the laser which provides the desired optical performance for the device, such as confining, reflecting or guiding the generated light in a desired direction. The cladding layers may be partially or entirely coextensive with the current injection layers.

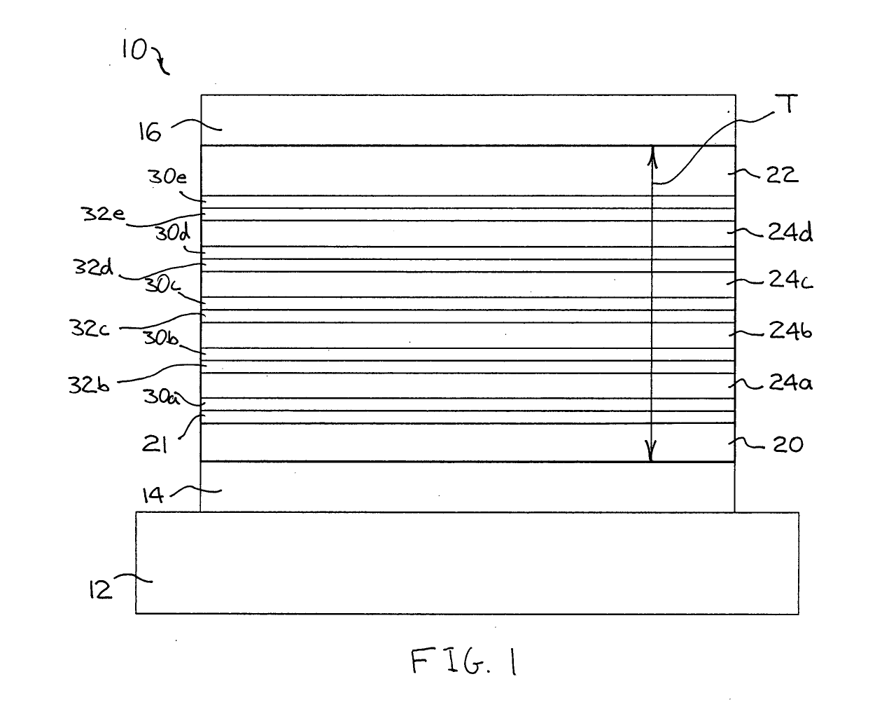

FIG. 1 illustrates an interband cascade laser structure 10 in accordance with an embodiment of the present invention. The structure 10 includes a substrate 12 made of any suitable material such as GaSb. A bottom cladding 14 is provided on the substrate 12. A top cladding 16 is provided at the upper portion of the structure 10. The bottom and top claddings 14 and 16 may be made of materials such as AlSb/InAs superlattices. The interband cascade laser structure 10 includes several spacer layers. A bottom spacer layer 20 is provided over the bottom cladding 14. A top spacer layer 22 is provided under the top cladding 16. Intermediate spacer layers 24a, 24b, 24c and 24d are embedded in the structure 10, as more fully described below.

As shown in FIG. 1, the interband cascade laser structure 10 includes a transition layer 21, which may be made of materials such as InAs and AlSb having a typical thickness of from about 100 to about 300 Å. The structure 10 includes multiple active layers 30a, 30b, 30c, 30d and 30e. The active layers 30a, 30b, 30c, 30d and 30e have typical thicknesses of from about 100 to about 500 Å, for example, from about 150 to about 250 Å. The active layers may be made of materials such as InAs, AlSb, GaSb and/or InGaSb. The interband cascade laser structure 10 also includes multiple injection layers 32b, 32c, 32d and 32e. The injection layers have typical thicknesses of from about 200 to about 1,000 Å, for example, from about 300 to about 600 Å. The injection layers may be made of materials such as InAs, AlSb and/or AlInSb.

The intermediate spacer layers 24a, 24b, 24c and 24d have thicknesses of at least about 10 Å, typically from about 50 to about 10,000 Å. For example, the spacer layers 24a, 24b, 24c and 24d may have thicknesses of from about 100 to about 5,000 Å. The bottom spacer layer 20 and the top spacer layer 22 have typical thicknesses of from about 10 to about 50,000 Å, for example, from about 500 to about 10,000 Å. In one embodiment, the bottom spacer layer 20 and/or the top spacer layer 22 have thicknesses greater than the thicknesses of each intermediate spacer layer 24a, 24b, 24c and 24d.

The addition of spacer layers in accordance with the present invention may broaden the active waveguide core thickness to a range of from about 2 or 3 micrometers to 15 micrometers or more. For example, the waveguide core thickness T shown in FIG. 1 may be from about 5 to about 15 micrometers.

In conventional interband cascade laser designs, the active waveguide core region may have one or many stages or pairs of active and injection regions. A typical design may contain anywhere between 1 and 40 repeats, for example, 18 repeats may be used. The thickness of one standard stage of an 18-cascade structure may be about 765 Å, resulting in a structure that is about 14,000 Å (1.4 micrometers) thick. The waveguide core of typical conventional interband cascade laser structures is thus less than 2 micrometers.

The spacer layers 20, 22, 24a, 24b, 24c and 24d have relatively high refractive indices, typically greater than 3. For example, the spacer layers may have refractive indices of from about 3.3 to about 4.5. As a particular example, the spacer layers may have refractive indices of from about 3.7 to about 3.9.

Typical spacer layers may comprise GaSb, InSb, GaAs, InAs, InAsSb, GaInSb, AlInAsSb, AlGaAsSb or AlSb. As a particular example, the spacer layers comprise GaSb. While GaSb is a particularly suitable spacer layer material for many applications, other materials may also be suitable. Table 1 lists some examples of spacer layer materials and their approximate refractive indices at a wavelength of 3.5 micrometers.

TABLE 1

| Spacer Layer Material | Refractive Index |
|---|---|
| GaSb | 3.8 |
| InSb | 4.0 |
| GaAs | 3.4 |
| InAs | 3.5 |
| InAsSb | 3.5-4.0 |
| GaInSb | 3.8-4.0 |
| AlInAsSb | 3.3-3.6 |
| AlGaAsSb | 3.3-3.7 |

It is noted that the refractive indices of the spacer layer materials is wavelength-dependent. Thus, while the refractive index of GaSb is about 3.8 at a wavelength of 3.5 micrometers, it may vary at other wavelengths.

The spacer layers may be electrically conductive, e.g., by doping the layers. Dopant levels for the spacer layers typically range from about 1·10¹⁷/cm⁻³ to about 1·10¹⁹/cm⁻³. For example, the dopant may be a p-type dopant comprising Be and/or Zn, or an n-type dopant comprising Te, Se and/or Si.

Doping may be used to control the conductivity of the spacer layer materials. If a spacer layer is used to inject current into the device, it may be highly doped, e.g., for GaSb, p-type dopant levels may be as high as 8·10¹⁸ cm⁻³, or lower for thicker spacer layers. If the spacer layer is not used to inject current, but still transports charge between active and injection layers, it may be moderately doped, e.g., for GaSb, p-type dopant levels may be about 2 to 4·10¹⁷ cm⁻³. if the spacer layer does not need to transport charge, it may be undoped.

The interband cascade laser structures of the present invention may comprise multiple repeating unit layers, with each unit layer comprising an active layer, a spacer layer on the active layer, and an injection on the spacer layer. A typical structure may comprise from 2 to 50 of the unit layers, for example, from 10 to 40 of the unit layers. As a particular example, the structure may comprise from 20 to 30 of the unit layers. Each repeating unit layer may have a total thickness greater than about 3 micrometers, typically from about 5 to about 15 micrometers.

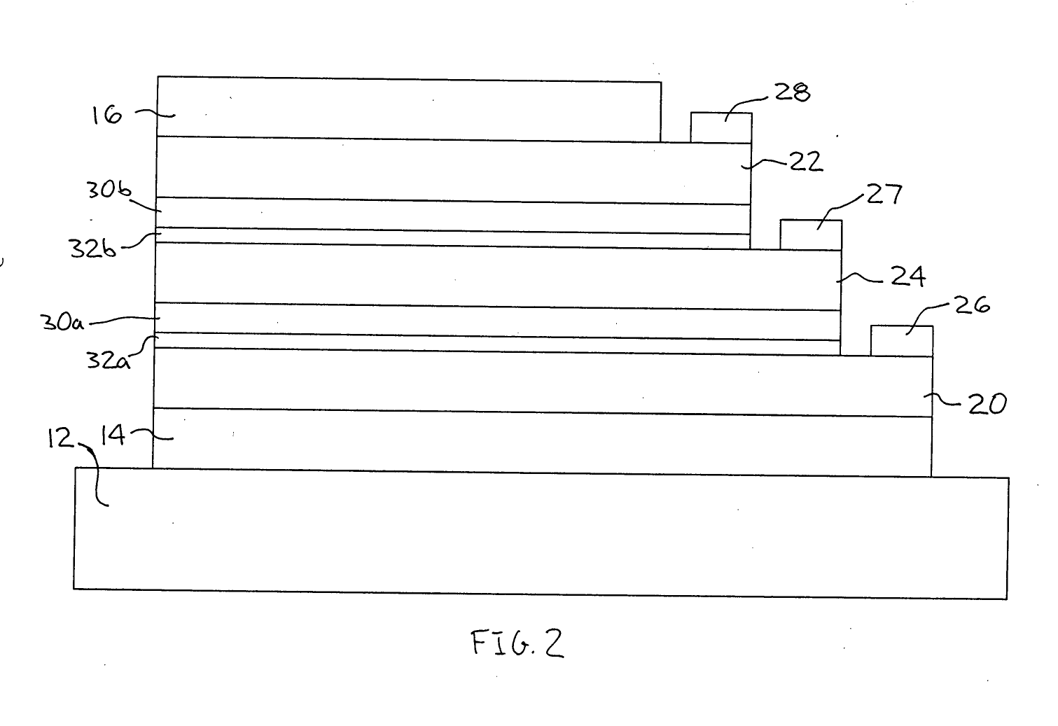

FIG. 2 shows an interband cascade laser 110 including a substrate 12, bottom cladding 14 and top cladding 16. A bottom spacer layer 20 is provided on the bottom cladding 14, and a top spacer layer 22 is provided under the top cladding 16. An intermediate spacer layer 24 is embedded between a first injection/active layer pair 30a, 32a, and a second active/injection layer pair 30b/32b. The spacer layers, 20, 24 and 22 form a step configuration having metal contacts 26, 27 and 28 deposited thereon, respectively.

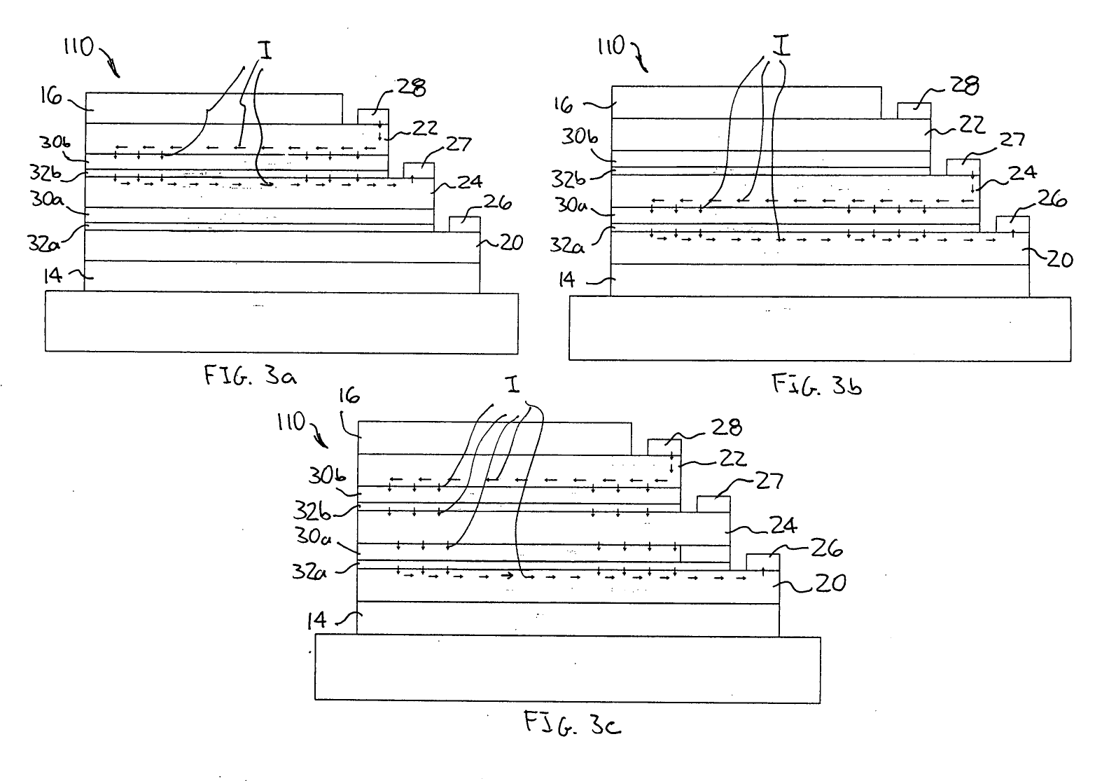

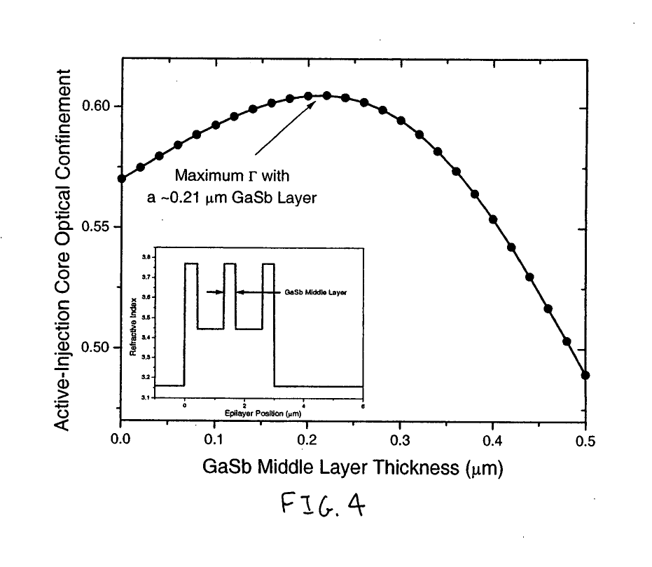

FIGS. 3a-3c illustrate selective activation of the interband cascade laser 110 of FIG. 2. In FIG. 3a, connections are made through the metal contacts 28 and 27 to provide a current path I which travels in the plane of the top spacer layer 22, through the active layer 30b and injection layer 32b, and in the plane of the intermediate spacer layer 24.

In FIG. 3b, current is applied through the metal contacts 27 and 26 and travels in a path I in the plane of the intermediate spacer layer 24, through the active layer 30a and injection layer 32a, and in the plane of the bottom spacer layer 20.

In FIG. 3c, current is applied to contacts 28 and 26 to create a current path I in the plane of the top spacer layer 22, through the active layer 30b, injection layer 32b, intermediate spacer layer 24, active layer 30a and injection layer 32a, and then in the plane of the bottom spacer layer 20.

An example of an interband cascade laser structure is provided in Table 2.

TABLE 2

| Material | Refractive Index | Layer Thickness |
|---|---|---|
| InAs/AlSb top cladding | 3.3 | 2.4 μm |
| GaSb Layer | 3.8 | 0.4 μm |
| Cascaded Stages | 3.45 | 0.9 μm |
| GaSb Layer | 3.8 | 0.4 μm |
| Cascaded Stages | 3.45 | 0.9 μm |
| GaSb Layer | 3.8 | 0.4 μm |
| InAs/AlSb bottom cladding | 3.3 | 2.4 μm |

The doped spacer layers may be used for current injection into the device, eliminating the need to dope the top and bottom cladding regions for current transport. Additionally, the active layers of the different core regions may be different. If ohmic contact is made to all three GaSb spacer layers, and they are doped sufficiently for lateral current transport, such a structure would allow selective operation of two independent active layers. While the structure set forth in Table 2 has only one high-index region embedded within the active region core, two or more embedded high-index layers could be provided. An example of an interband cascade laser structure having two embedded spacer layers is provided in Table 3.

TABLE 3

| Material | Refractive Index | Layer Thickness |
|---|---|---|
| InAs/AlSb top cladding | 3.3 | 2.4 μm |
| GaSb Layer | 3.8 | 0.4 μm |
| Cascaded Stages | 3.45 | 0.6 μm |
| GaSb Layer | 3.8 | 0.3 μm |
| Cascaded Stages | 3.45 | 0.6 μm |
| GaSb Layer | 3.8 | 0.3 μm |
| Cascaded Stages | 3.45 | 0.6 μm |
| GaSb Layer | 3.8 | 0.4 μm |
| InAs/AlSb bottom cladding | 3.3 | 2.4 μm |

The thickness of each region of cascaded stages set forth in Table 3 has been reduced to 0.6 micrometers, while the same total active region thickness of 1.8 micrometers is maintained. The number and thicknesses of the high-index spacer layers placed between and around the cascaded stage layers may be selected as desired. This allows for great flexibility in tailoring the optical mode profile to suit a particular application or device geometry.

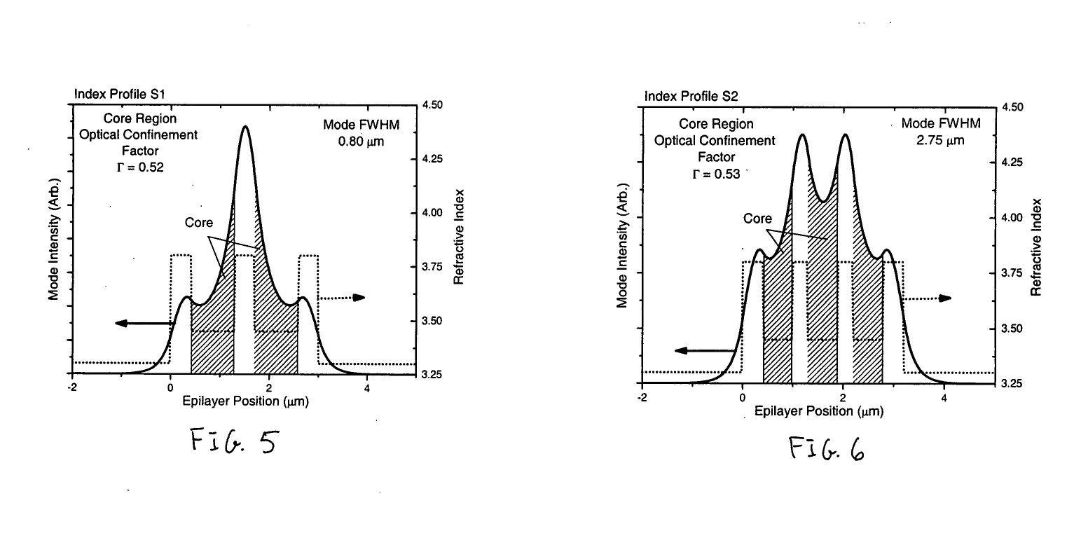

FIGS. 5 and 6 illustrate refractive index and calculated mode profiles for the structures of Table 2 and Table 3. The mode profile of the structure of Table 2 having a single intermediate or embedded spacer layer is shown in FIG. 5. The mode profile of the structure of Table 3 having two embedded spacer layers is shown in FIG. 6.

Structures having single GaSb spacer layers adjacent to the laser core active region have been fabricated, tested, and shown to perform well in comparison with standard IC lasers. Two such samples, #M67 and #M99, used a single GaSb layer below the active region and above the non-conducting lower cladding. The general arrangement of these structures is shown in Table 4 below, with the GaSb layer indicated. The thickness (0.3 and 0.4 micrometers) and doping (p-doped with Be at 8·10¹⁸cm⁻³) of these GaSb layers are comparable to those used in the broadened waveguide structures described above. The successful demonstration of lasers from these structures indicates that electrical contacting to the buried layers was successful, lateral transport into the devices was effective, and the high-refractive-index GaSb layer did not overly distort the optical mode profile.

TABLE 4

| M67 IC laser structure | M99 IC laser structure |
|---|---|
| N-InAs top contact | N-InAs top contact |
| N-doped InAs/AlSb top cladding | N-doped InAs/AlSb top cladding |
| Active region | Active region |
| 0.4 μm P = 8 · 10¹⁸ cm⁻³ | 0.3 μm P = 8 · 10¹⁸ cm⁻³ |
| GaSb spacer layer | GaSb spacer layer |
| Undoped AlAsSb cladding | Undoped AlAsSb cladding |
| P-GaSb substrate | P-GaSb substrate |

Wafer M286 is an operational test of the present spacer layer structure. The design of M286 is a modification of a standard interband cascade laser, using doped GaSb spacer layers both between and below the active and injection layers in the core of the waveguide. M286 was grown by molecular beam epitaxy (MBE) on a GaSb substrate. The lower waveguide cladding layer consisted of 30,000 Å of a digital AlAs/AlSb superlattice. The waveguide core consists of a 4,000 Å GaSb spacer and current injection layer, followed by a series of injection, active, and GaSb spacer layers. The total thickness of the waveguide core region is 57,000 Å. The upper waveguide cladding layer consists of a 14,000 Å InAs/AlSb superlattice. This structure is shown schematically in Table 5 below. The active/injector/spacer layer structure is repeated for a total of 24 periods. The total core thickness of 57,000 Å (5.7 micrometers) represents a significant increase over the standard interband cascade laser core design.

TABLE 5

| | | | |
|---|---|---|---|
| Layer | Composition | Thickness (Å) | Doping |

M286 Wafer Schematic

| | | | |
|---|---|---|---|
| Cap | InAs | 350 | |
| Transition | (multiple) | 570 | — |
| Top cladding | InAs/AlSb SL | 14,000 | — |
| Connection | (multiple) | 100 | — |
| Injector | (multiple) | 350 | — |

(Repeated Active/Spacer/Injector layers)

| | | | |
|---|---|---|---|
| Active | (multiple) | 220 | — |
| Injector | (multiple) | 350 | — |
| Spacer | GaSb | 1,600 | p-doped |
| | | | 3.5 * 10¹⁷ cm⁻³ |
| Active | (multiple) | 220 | — |
| Transition | (multiple) | 530 | — |
| Current injection/ | GaSb | 4,000 | p-doped |
| Spacer | | | 8 * 10¹⁸ cm⁻³ |
| Bottom cladding | AlAs/AlSb SL | 30,000 | Undoped |
| Buffer | GaSb | 3,000 | Undoped |
| Substrate | GaSh | — | p-type |

After growth, edge-emitting lasers were fabricated from this material using standard techniques. Laser mesas were defined using chemical etching, an electrically isolating Si₃N₄ layer was deposited, and an ohmic contact metallization layer was deposited above both the laser mesa and insulating layer. The devices lased successfully.

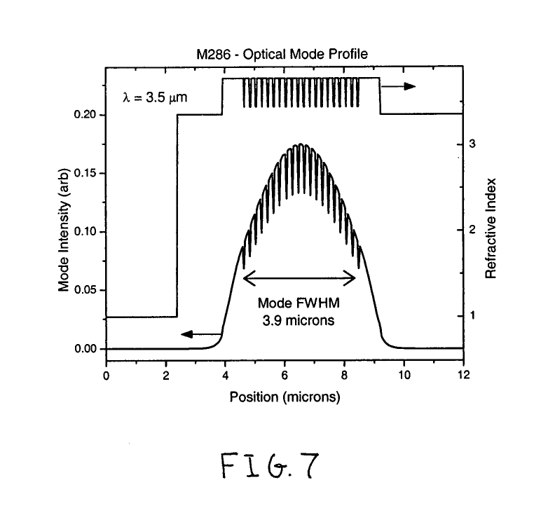

FIG. 7 shows the calculated optical mode profile for this structure. The full-width-half-max (FWHM) of the profile is 3.9 micrometers, larger than the calculated 1.8 micrometer FWHM of a typical interband cascade laser device.

This design used an outer spacer layer below, but not above, the repeated active/injection/spacer periods. The outer layer, doubling as a current injection layer, facilitated current conduction into the core region. This allowed for the use of an AlAs/AlSb superlattice, instead of an InAs/AlSb superlattice bottom cladding layer.

This design used the GaSb spacer layers between each pair of active and injection layers. However, a similar effect might be achieved, for example, with fewer (but thicker) GaSb spacer layers, spaced every few pairs of active and injection layers.

The present spacer layer structures provide several advantages. The waveguide structure and its fundamental optical mode may be considerably broader, thus reducing the far field divergence and therefore increasing optical brightness. Increased confinement of the optical mode to the active region of the laser may be achieved, due to the nature and placement of the high refractive index spacer layer within and surrounding the active region. Better optical confinement within the active region leads to a reduction in the peak material gain necessary to achieve lasing, and therefore to a lower threshold current. A reduction in the laser's linewidth enhancement factor may be provided, allowing for improved high-temperature and high-power operation as a result of the reduced tendency toward filamentation. High refractive index spacer layers which are lattice-matched to the growth substrate will not add additional strain to the epitaxial layer. Furthermore, the use of doped layers within the cascaded active/injection region structure allows for selective current injection into the active region cascades, providing greater wavelength tunability than is currently achievable in conventional interband cascade lasers.

Whereas particular embodiments of this invention have been described above for purposes of illustration, it will be evident to those skilled in the art that numerous variations of the details of the present invention may be made without departing from the invention.

1. An interband cascade laser structure comprising:
a first pair of active and injection layers;
a second pair of active and injection layers; and
a spacer layer between the first and second pairs of active and injection layers.

2. The interband cascade laser structure of claim 1, wherein the spacer layer has a thickness of at least about 10 Å.

3. The interband cascade laser structure of claim 1, wherein the spacer layer has a thickness of from about 50 to about 10,000 Å.

4. The interband cascade laser structure of claim 1, wherein the spacer layer has a thickness of from about 100 to about 5,000 Å.

5. The interband cascade laser structure of claim 1, wherein the spacer layer has a refractive index greater than 3.

6. The interband cascade laser structure of claim 1, wherein the spacer layer has a refractive index of from about 3.3 to about 4.5.

7. The interband cascade laser structure of claim 1, wherein the spacer layer has a refractive index of from about 3.7 to about 3.9.

8. The interband cascade laser structure of claim 1, wherein the spacer layer is electrically conductive.

9. The interband cascade laser structure of claim 1, wherein the spacer layer comprises GaSb, InSb, GaAs, InAs, InAsSb, GaInSb, AlInAsSb, AlGaAsSb or AlSb.

10. The interband cascade laser structure of claim 9, wherein the spacer layer is doped.

11. The interband cascade laser structure of claim 10, wherein the spacer layer comprises from about 1·10¹⁷/cm⁻³ to about 1·10¹⁹/cm⁻³ of the dopant.

12. The interband cascade laser structure of claim 10, wherein the dopant is a p-type dopant comprising Be and/or Zn.

13. The interband cascade laser structure of claim 10, wherein the dopant is an n-type dopant comprising Te, Se and/or Si.

14. The interband cascade laser structure of claim 1, wherein the spacer layer comprises GaSb.

15. The interband cascade laser structure of claim 14, wherein the GaSb is doped with Be and/or Zn.

16. The interband cascade laser structure of claim 1, wherein the active layers have thicknesses of from about 100 to about 500 Å.

17. The interband cascade laser structure of claim 1, wherein the injection layers have thicknesses of from about 200 to about 1,000 Å.

18. The interband cascade laser structure of claim 1, wherein the active layers comprise InAs, AlSb, GaSb and/or InGaSb.

19. The interband cascade lasear structure of claim 1, wherein the injection layers comprise InAs, AlSb and/or AlInSb.

20. An interband cascade laser structure comprising multiple repeating unit layers, wherein each unit layer comprises:
an active layer;
a spacer layer on the active layer; and
an injection layer on the spacer layer.

21. The interband cascade laser structure of claim 20, wherein the structure has from 2 to 50 of the unit layers.

22. The interband cascade laser structure of claim 20, wherein the structure has from 10 to 40 of the unit layers.

23. The interband cascade laser structure of claim 20, wherein the structure has from 20 to 30 of the unit layers.

24. The interband cascade laser structure of claim 20, wherein the multiple repeating unit layers have a total thickness greater than 3 micrometers.

25. The interband cascade laser structure of claim 20, wherein the multiple repeating unit layers have a total thickness of from about 5 to about 15 micrometers.

26. The interband cascade laser structure of claim 20, wherein each active layer has a thickness of from about 100 to about 500 Å, each spacer layer has a thickness of from about 100 to about 5,000 Å, and each injection layer has a thickness of from about 200 to about 1,000 Å.

27. The interband cascade laser structure of claim 20, wherein each spacer layer has a refractive index greater than about 3.3.

28. The interband cascade laser structure of claim 20, wherein the spacer layer comprises GaSb, InSb, GaAs, InAs, InAsSb, GaInSb, AlInAsSb, AlGaAsSb or AlSb.

29. The interband cascade laser structure of claim 28, wherein the spacer layer is doped.

30. The interband cascade laser structure of claim 20, wherein the active layers have thicknesses of from about 100 to about 500 Å.

31. The interband cascade laser structure of claim 20, wherein the injection layers have thicknesses of from about 200 to about 1,000 Å.

32. The interband cascade laser structure of claim 20, wherein each active layer comprises InAs, AlSb, GaSb and/or InGaSb.

33. The interband cascade laser structure of claim 20, wherein each injection layer comprises InAs, AlSb and/or AlInSb.

34. An interband cascade laser structure comprising:
a bottom cladding layer;
a bottom spacer layer over the bottom cladding layer;
a transition layer over the bottom spacer layer;
a first active layer over the transition layer;
a second spacer layer over the first active layer;
a first injection layer over the second spacer layer;
a second active layer over the first injection layer;
a top spacer layer over the second active layer; and
a top cladding layer over the top spacer layer.

35. The interband cascade laser structure of claim 34, wherein the bottom spacer layer and the top spacer layer have thicknesses of from about 10 to about 50,000 Å.

36. The interband cascade laser structure of claim 34, wherein the bottom spacer layer and the top spacer layer have thicknesses of from about 500 to about 10,000 Å.

37. The interband cascade laser structure of claim 34, wherein the second spacer layer has a thickness of from about 100 to about 5,000 Å.

38. The interband cascade laser structure of claim 34, wherein the second spacer layer has a thickness less than a thickness of at least one of the bottom and top spacer layers.

39. The interband cascade laser structure of claim 34, wherein the bottom, second and top spacer layers have refractive indicies greater than about 3.3.

40. The interband cascade laser structure of claim 34, wherein the bottom, second and top spacer layers comprise the same material.

41. The interband cascade laser structure of claim 34, wherein the bottom, second and top spacer layers comprise GaSb, InSb, GaAs, InAs, InAsSb, GaInSb, AlInAsSb, AlGaAsSb or AlSb.

42. The interband cascade laser structure of claim 41, wherein the bottom, second and top spacer layers are doped.

43. The interband cascade laser structure of claim 34, wherein the distance between the bottom cladding layer and the top cladding layer is greater than 3 micrometers.

44. The interband cascade laser structure of claim 34, wherein the distance between the bottom cladding layer and the top cladding layer is from about 5 to about 15 micrometers.

45. The interband cascade laser structure of claim 34, further comprising at least one additional spacer layer, at least one additional injection layer, and at least one additional active layer between the second active layer and the top spacer layer.

46. The interband cascade laser structure of claim 45, comprising from 2 to 40 of each of the additional spacer, injection and active layers.
